(19) United States
(12) Patent Application Publication
(10) Pub. No.: US 2025/0095990 A1
(43) Pub. Date: Mar. 20, 2025

(54) METAL-CONTAINING HARDMASK OPENING METHODS USING BORON-AND-HALOGEN-CONTAINING PRECURSORS

(71) Applicant: Applied Materials, Inc., Santa Clara, CA (US)

(72) Inventors: Han Wang, Sunnyvale, CA (US); Jiaheng Yu, Sunnyvale, CA (US); Gene H. Lee, San Jose, CA (US)

(73) Assignee: Applied Materials, Inc., Santa Clara, CA (US)

(21) Appl. No.: 18/817,646

(22) Filed: Aug. 28, 2024

Related U.S. Application Data
(60) Provisional application No. 63/539,189, filed on Sep. 19, 2023.

(51) Int. Cl. H01L 21/033; H01L 21/02; H01L 21/311; H01L 21/3213

(52) U.S. Cl. CPC H01L 21/0337; H01L 21/02164; H01L 21/0332; H01L 21/31122; H01L 21/31144; H01L 21/32137; H01L 21/32139

(57) ABSTRACT

Exemplary semiconductor processing methods may include providing a boron-and-halogen-containing precursor and an oxygen-containing precursor to a processing region of a semiconductor processing chamber. A substrate may be housed in the processing region. A layer of metal-containing hardmask material may be disposed on the substrate. A layer of silicon-containing material may be disposed on the layer of metal-containing hardmask material. The methods may include forming plasma effluents of the boron-and-halogen-containing precursor and the oxygen-containing precursor. The methods may include contacting the substrate with the plasma effluents of the boron-and-halogen-containing precursor and the oxygen-containing precursor. The contacting may etch a feature in the layer of metal-containing hardmask material. The contacting may form a layer of passivation material on sidewalls of the feature in the layer of metal-containing hardmask material.

### CROSS-REFERENCE TO RELATED APPLICATIONS

This application claims the benefit of, and priority to U.S. Provisional Application Ser. No. 63/539,189, filed Sep. 19, 2023, which is hereby incorporated by reference in its entirety for all purposes.

### TECHNICAL FIELD

The present technology relates to semiconductor processes and equipment. More specifically, the present technology relates to etching operations of metal-containing hardmask materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a boron-and-halogen-containing precursor and an oxygen-containing precursor to a processing region of a semiconductor processing chamber. A substrate may be housed in the processing region. A layer of metal-containing hardmask material may be disposed on the substrate. A layer of silicon-containing material may be disposed on the layer of metal-containing hardmask material. The methods may include forming plasma effluents of the boron-and-halogen-containing precursor and the oxygen-containing precursor. The methods may include contacting the substrate with the plasma effluents of the boron-and-halogen-containing precursor and the oxygen-containing precursor. The contacting may etch a feature in the layer of metal-containing hardmask material. The contacting may form a layer of passivation material on sidewalls of the feature in the layer of metal-containing hardmask material.

In some embodiments, the boron-and-halogen-containing precursor may be or include boron trichloride (BCl₃). The oxygen-containing precursor may be or include diatomic oxygen (O₂). The layer of metal-containing hardmask material may include tungsten. The methods may include providing a halogen-containing precursor to the processing region with the boron-and-halogen-containing precursor. The halogen-containing precursor may be or include diatomic chlorine (Cl₂), hydrogen bromide (HBr), or both. The layer of metal-containing hardmask material may be characterized by a metal content of greater than or about 40 at. %. The layer of silicon-containing material may be or include silicon oxide. The layer of passivation material may be or include a boron-and-oxygen-containing material. The feature in the layer of metal-containing hardmask material may be characterized by a critical dimension of less than or about 20 nm. The semiconductor processing chamber operating temperature may be greater than or about 20° C. The boron-and-halogen-containing precursor and the oxygen-containing precursor may be silicon-free.

Some embodiments of the present technology may encompass semiconductor processing methods. The methods may include i) providing a boron-and-halogen-containing precursor to a processing region of a semiconductor processing chamber. A substrate may be housed in the processing region. A layer of metal-containing hardmask material may be disposed on the substrate. A layer of silicon-containing material may be disposed on the layer of metal-containing hardmask material. The methods may include ii) forming plasma effluents of the boron-and-halogen-containing precursor. The methods may include iii) contacting the substrate with the plasma effluents of the boron-and-halogen-containing precursor. The contacting may etch a feature in the layer of metal-containing hardmask material. The methods may include iv) providing an oxygen-containing precursor to the processing region of the semiconductor processing chamber. The methods may include v) contacting the substrate with the oxygen-containing precursor. The contacting may oxidize a portion of sidewalls of the feature in the layer of metal-containing hardmask material.

In some embodiments, the methods may include providing one or more halogen-containing precursors to the processing region of the semiconductor processing chamber with the boron-and-halogen-containing precursor. A flow rate ratio of the one or more halogen-containing precursors relative to the boron-and-halogen-containing precursor may be greater than or about 50:1. Operations i) through v) may be repeated for a second cycle. Repeating operation iii) in the second cycle may form a layer of passivation material on the sidewalls of the feature in the layer of metal-containing hardmask material.

Some embodiments of the present technology may encompass semiconductor processing methods. The methods may include providing a boron-and-halogen-containing precursor to a processing region of a semiconductor processing chamber. A substrate may be housed in the processing region. A layer of metal-containing hardmask material may be disposed on the substrate. A patterned layer of silicon-containing material may be disposed on the layer of metal-containing hardmask material. The methods may include forming plasma effluents of the boron-and-halogen-containing precursor. The methods may include contacting the substrate with the plasma effluents of the boron-and-halogen-containing precursor. The contacting may etch a first portion of a feature in the layer of metal-containing hardmask material. The methods may include providing an oxygen-containing precursor to the processing region of the semiconductor processing chamber. The methods may include contacting the substrate with the oxygen-containing precursor. The contacting may oxidize sidewalls of the feature in the layer of metal-containing hardmask material. The methods may include providing the boron-and-halogen-containing precursor to the processing region of the semiconductor processing chamber. The methods may include forming plasma effluents of the boron-and-halogen-containing precursor. The methods may include contacting the substrate with the plasma effluents of the boron-and-halogen-containing precursor. The contacting may etch a second portion of the feature in the layer of metal-containing hardmask material. The contacting may form a layer of passivation material on sidewalls of the feature in the layer of metal-containing hardmask material.

In some embodiments, the boron-and-halogen-containing precursor may be or include boron trichloride (BCl₃). The methods may include forming plasma effluents of the oxygen-containing precursor.

Such technology may provide numerous benefits over conventional systems and techniques. For example, the processes may increase passivation of sidewall material of metal-containing hardmask materials during etch operations. Additionally, the processes may prevent pattern liftoff or collapse due to poor sidewall passivation associated with conventional technologies. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

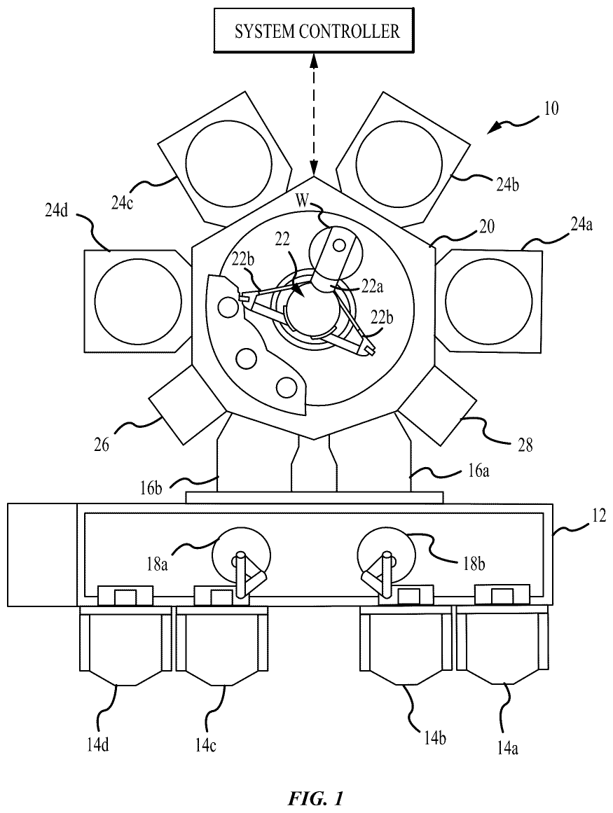

FIG. 1 shows a top plan view of an exemplary processing system according to some embodiments of the present technology.

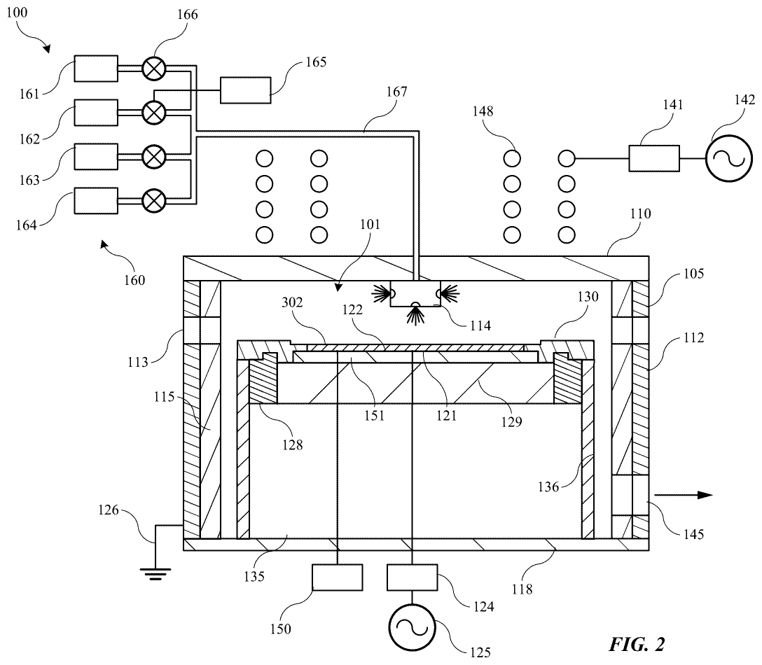

FIG. 2 shows a schematic cross-sectional view of an exemplary processing chamber according to some embodiments of the present technology.

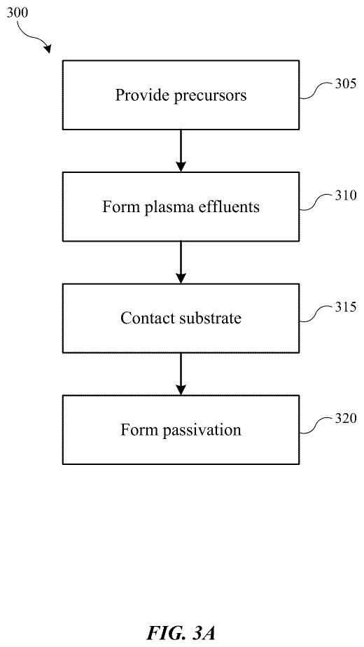

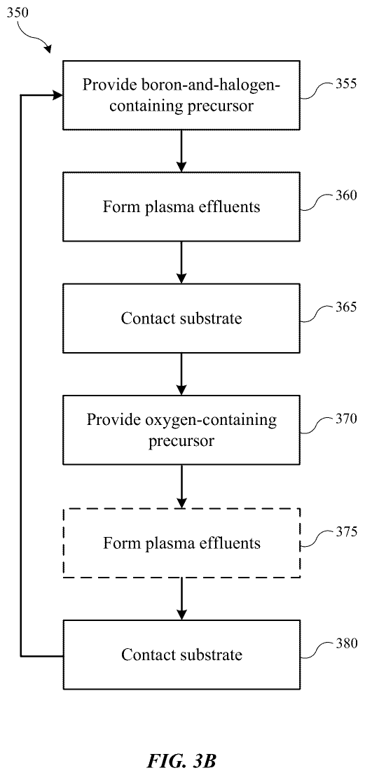

FIGS. 3A-3B show selected operations in etching methods according to some embodiments of the present technology.

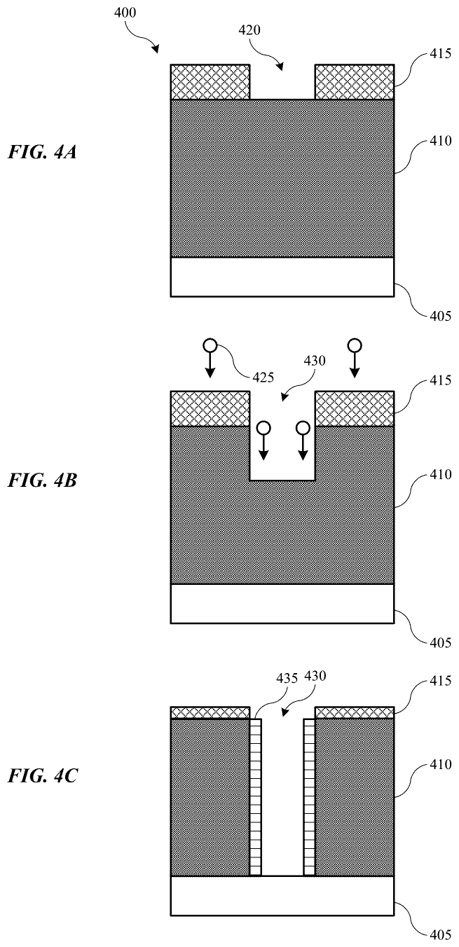

FIGS. 4A-4C illustrate cross-sectional views of substrate materials on which selected operations are being performed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As structures evolve, the aspect ratios of features and other structures increase, sometimes dramatically. During semiconductor processing, features may be etched through one or more materials, such as a layer of metal-containing hardmask material. When the features are formed, apertures may extend through an entire thickness of the layer of metal-containing hardmask material before accessing the substrate or other underlying materials. As aspect ratios of the features and other structures increase, the resultant features or apertures may be characterized by reduced critical dimensions. It is desired that these critical dimensions be uniform throughout the features or aperture.

Conventional technologies have typically etched features into metal-containing hardmask material using halogen-containing precursors. To form passivation material on sidewalls of the metal-containing hardmask material, an oxygen-containing precursor may be provided to form a metal-and-oxygen-containing passivation material. However, as metal in contents of hardmask materials continue to increase, the metal-and-oxygen-containing passivation material may not be strong enough to passivate sidewalls of the metal-containing hardmask material. Other conventional technologies have included a silicon-containing precursor and/or oxygen-containing precursor to form silicon-and-oxygen-containing passivation material, but this material may deposit silicon-and-oxygen-containing material at the etch front that may reduce the etch selectivity in the hardmask open processes. Yet other conventional technologies have included bromine-containing precursors to form metal-and-bromine-containing passivation material, but at increased temperatures, this material may volatize. Accordingly, conventional technologies have struggled to uniformly etch metal-containing hardmask material due to underperforming passivation techniques.

The present technology overcomes these issues by performing an etch process using a combination of precursors, such as a boron-and-halogen-containing precursor and an oxygen-containing precursor, cither simultaneously or sequentially, to provide strong passivation material on sidewalls of the features being etched. The present technology may provide boron-and-oxygen-containing passivation material that is much stronger than conventional metal-and-oxygen-containing material. The present technology may also avoid undesirable deposition issues associated with silicon-containing precursors. Finally, the boron-and-oxygen-containing passivation material of the present technology may be more resilient to increased temperatures.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described. Similarly, although a specific etching operation will be described, it is to be understood that the processes may be equally applicable to other processes in which etching may be performed. Accordingly, the examples given should not be considered to limit the scope of the described technology.

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

FIG. 2 illustrates a schematic cross-sectional view of an exemplary processing chamber 100 suitable for patterning a material layer disposed on a substrate 302 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 302 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 302 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as H₂, NH₃, H₂O, H₂O₂, o₂, O₃, NF₃, HF, F₂, CH₄, CF₄, CHF₃, C₂F₆, C₂F₄, C₃F₆, C₄F₆, C₄F₈, BrF₃, CIF₃, SF₆, CH₃F, CH₂F₂, BCl₃, PF₃, PH₃, COS, and SO₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 302 during processing. The substrate support pedestal 135 may include an electrostatic chuck (“ESC”) 122 for holding the substrate 302 during processing. The electrostatic chuck 122 may use the electrostatic attraction to hold the substrate 302 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 302 seated on the pedestal. The RF power supply 125 may cycle on and off, or pulse, during processing of the substrate 302. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 500 volts to about 15,000 volts to the electrode 121. The power source 150 may also include a system controller for controlling the operation of the electrode 121 by directing a DC current to the electrode 121 for chucking and de-chucking the substrate 302. For example, similar to the RF power supply 125, power supply 150 may provide a bias which attracts plasma ions, formed by the process gases in the chamber volume 101, to the ESC 122 and substrate 302 seated on the pedestal. The power supply 150 may cycle on and off, or pulse, during processing of the substrate 302. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 302 disposed thereon. The ESC 122 may be configured to perform in the temperature range required by the thermal budget of the device being fabricated on the substrate 302. For example, the ESC 122 may be configured to maintain the substrate 302 at a temperature of about −150° C. or lower to about 500° C. or higher depending on the process being performed.

The cooling base 129 may be provided to assist in controlling the temperature of the substrate 302. To mitigate process drift and time, the temperature of the substrate 302 may be maintained substantially constant by the cooling base 129 throughout the time the substrate 302 is in the cleaning chamber. In some embodiments, the temperature of the substrate 302 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 302, while shielding the top surface of the substrate support pedestal 135 from the plasma environment inside the plasma processing chamber 100. Lift pins may be selectively translated through the substrate support pedestal 135 to lift the substrate 302 above the substrate support pedestal 135 to facilitate access to the substrate 302 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

The chambers discussed previously may be used in performing exemplary methods including etching methods. Turning to FIGS. 3A-3B are shown exemplary operations in method 300 and method 350 according to embodiments of the present technology. Prior to the first operation of the method a substrate may be processed in one or more ways before being placed within a processing region of a chamber in which method 300 or method 350 may be performed. For example, a layer of metal-containing hardmask material may be formed on the substrate. Additionally, a layer of silicon-containing material, such as silicon oxide, may be formed on the layer of metal-containing hardmask material and then one or more patterns may be formed through the layer of silicon-containing material. Some or all of these operations may be performed in chambers or system tools as previously described, or may be performed in different chambers on the same system tool, which may include the chamber in which the operations of method 300 and/or method 350 are performed.

Method 300 and/or method 350 may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 and/or method 350 describe operations shown schematically in FIGS. 4A-4C, the illustrations of which will be described in conjunction with the operations of method 300 and method 350. It is to be understood that FIGS. 4A-4C illustrate only partial schematic views, and a substrate may contain any number of structural sections having aspects as illustrated in the figures, as well as alternative structural aspects that may still benefit from operations of the present technology.

Method 300 and/or method 350 may or may not involve optional operations to develop the semiconductor structure prior to a particular fabrication operation. It is to be understood that method 300 and/or method 350 may be performed on any number of semiconductor structures, and FIG. 4A illustrates one exemplary structure within which a contact cleaning or etching process may be performed. As illustrated in FIG. 4A, a processed semiconductor structure 400 may include a substrate 405, which may have a layer of metal-containing hardmask material 410, such as a metal-and-boron-containing material, a metal-and-carbon-containing material, or a metal-and-silicon-containing material. The layer of metal-containing hardmask material 410 may be characterized by a metal content of greater than or about 10 at. %, and may be characterized by a metal content of greater than or about 15 at. %, greater than or about 20 at. %, greater than or about 25 at. %, greater than or about 30 at. %, greater than or about 35 at. %, greater than or about 40 at. %, greater than or about 45 at. %, greater than or about 50 at. %, greater than or about 55 at. %, greater than or about 60 at. %, greater than or about 65 at. %, greater than or about 70 at. %, greater than or about 75 at. %, greater than or about 80 at. %, or more. In embodiments, the layer of metal-containing hardmask material 410 may be a layer of a tungsten-containing hardmask material (e.g., tungsten boride, tungsten carbide, tungsten silicide, etc.) overlying the substrate 405. However, it is contemplated that the hardmask material 410 is not limited to metal and may include any other material such as, but not limited to, arsenic (As), gold (Au), chromium (Cr), iron (Fe), gallium (Ga), germanium (Ge), hafnium (Hf), molybdenum (Mo), niobium (Nb), antimony (Sb), tin (Sn), tantalum (Ta), vanadium (V), zirconium (Zr), indium (In), or any other material useful in hardmask applications.

A layer of silicon-containing material 415 may overly the layer of metal-containing hardmask material 410 and may be patterned to form one or more apertures 420 extending through the layer of silicon-containing material 415. In embodiments, the layer of silicon-containing material 415 may be silicon oxide or any other silicon-containing material. The one or more apertures 420 may be defined by sidewalls that may be composed of the layer of silicon-containing material 415. It is to be understood that the noted structure is not intended to be limiting, and any of a variety of other semiconductor structures are similarly encompassed. Other exemplary structures may include two-dimensional and three-dimensional structures common in semiconductor manufacturing, and within which an oxygen-containing material is to be removed relative to one or more other materials. Additionally, although a high aspect ratio structure may benefit from the present technology, the technology may be equally applicable to lower aspect ratios and any other structures.

As shown in the figures, multiple materials may be present and exposed to etchant materials. The method 300 and/or method 350 may be performed to etch or remove a portion of the layer of metal-containing hardmask material 410 exposed within the aperture 420, while minimizing etching of other materials, such as the overlying layer of silicon-containing material 415. By utilizing processing conditions (e.g., temperature) and precursors according to embodiments of the present technology, etch rates of the layer of metal-containing hardmask material 410 relative to the layer of silicon-containing material 415 may be increased. Additionally, profile control of the feature etched into the layer of metal-containing hardmask material 410 may be more uniform compared to conventional technologies.

Operation 305 of method 300 and operation 355 of method 350 may include providing precursors, such as etchant precursors, into a processing region. The processing region may house a substrate 405, such as processed semiconductor structure 400, which may have one or more layers of material, such as the layer of metal-containing hardmask material 410 and the layer of silicon-containing material 415 disposed on the substrate 405, for example. The layer of metal-containing hardmask material 410 may be exposed within an opening or aperture 420 in the layer of silicon-containing material 415. The precursors may include a boron-and-halogen-containing precursor, an oxygen-containing precursor, and/or a halogen-containing precursor. In embodiments, one or more inert gases or carrier gases may be provided with the precursors. For example, the precursors may include any number of carrier gases, which may include argon (Ar), helium (He), nitrogen, or other noble, inert, or useful precursors. The carrier gases may be used to dilute the precursors, which may further reduce etching rates to allow adequate diffusion through the aperture. Plasma effluents may be formed, such as within the processing region of the semiconductor processing chamber, at operation 310 of method 300 and operation 360 of method 350. The plasma effluents may include plasma effluents of any of the precursors previously discussed. Operations 305 and 310 as well as operations 355 and 360 may occur in a variety of orders, and may be performed substantially simultaneously in some embodiments. Additionally, the plasma may be formed initially from either precursor or from one or more inert gases prior to addition of the etchant precursors in different embodiments.

As illustrated in FIG. 4B, semiconductor structure 400 and substrate 405 may be contacted with the plasma effluents 425 of the etchant precursors at operation 315 of method 300 and operation 365 of method 350, which may perform an etch or removal of the layer of metal-containing hardmask material 410 to form a feature 430 in the layer of metal-containing hardmask material 410. The plasma effluents 425 may contact the semiconductor structure 400, and may contact all exposed surfaces, including surfaces to be etched, such as the layer of metal-containing hardmask material 410, as well as surfaces to be maintained, such as the layer of silicon-containing material 415.

Additionally, as shown in FIG. 4C, at optional operation 320 of method 300, a passivation material 435, such as a layer of boron-and-oxygen-containing material, may be formed on sidewalls of the layer of metal-containing hardmask material 410 defining the feature 430. In method 350, a separate passivation process may be performed as the precursors provided at operation 355 may or may not include the oxygen-containing precursor. In embodiments, method 350 may include providing an oxygen-containing precursor to the processing region of the semiconductor processing chamber at operation 370. At optional operation 375, method 350 may include forming plasma effluents of the oxygen-containing precursor. At operation 380, method 350 may include contacting the substrate with the oxygen-containing precursor or plasma effluents thereof. The contacting may oxidize a portion of sidewalls of the feature 430 in the layer of metal-containing hardmask material 410. Residual boron material from the boron-and-halogen-containing precursor may react with the oxidized portion of sidewalls of the feature 430 in the layer of metal-containing hardmask material 410 to form the passivation material 435. Alternatively, some or all of the operations of method 350 may be repeated for additional cycles and the boron-and-halogen-containing precursor may react with the oxidized portion of sidewalls of the feature 430 in the layer of metal-containing hardmask material 410 to form the passivation material 435.

Precursors used in the etching processes may include a boron-and-halogen-containing precursor, an oxygen-containing precursor, and/or a halogen-containing precursor, as well as one or more inert gases or carrier gases. An exemplary boron-and-halogen-containing precursor may be or include boron trichloride (BCl₃), which may be provided to the processing region. Other sources of boron-and-halogen may be used in conjunction with or as replacements for the BCl₃. For example, the boron-and-halogen-containing precursor may be or include boron trifluoride (BF₃) or additional boron-and-halogen-containing materials. In embodiments, the boron-and-halogen-containing precursor and the oxygen-containing precursor may be silicon-free. Additionally, the processing region may be maintained free of silicon and/or silicon delivery during the etching processes. An exemplary oxygen-containing precursor may be or include diatomic oxygen (O₂), which may be provided to the processing region. Other sources of oxygen may be used in conjunction with or as replacements for the O₂. For example, the oxygen-containing precursor may include one or more materials including ozone (O₃), steam (H₂O), hydrogen peroxide (H₂O₂), or additional oxygen-containing materials. An exemplary halogen-containing precursor may be or include diatomic chlorine (Cl₂), which may be provided to the processing region. Other sources of halogen may be used in conjunction with or as replacements for the Cl₂. For example, the halogen-containing precursor may be or include titanium tetrachloride (TiCl₄), diatomic fluorine (F₂), nitrogen trifluoride (NF₃), hydrogen fluoride (HF), or additional halogen-containing materials. By providing an additional halogen-containing precursor etch rates may be increased.

A flow rate ratio of the one or more halogen-containing precursors relative to the boron-and-halogen-containing precursor may be maintained to balance an amount of etching with an amount of passivation. In embodiments, a flow rate ratio of the one or more halogen-containing precursors relative to the boron-and-halogen-containing precursor may be greater than or about 50:1, and may be greater than or about 55:1, greater than or about 60:1, greater than or about 65:1, greater than or about 70:1, greater than or about 75:1, greater than or about 80:1, greater than or about 85:1, greater than or about 90:1, greater than or about 95:1, greater than or 100:1, or more, although the flow rate ratio of the one or more halogen-containing precursors relative to the boron-and-halogen-containing precursor may also be included in ranges between any two of these stated numbers or within any smaller range encompassed by any of the stated ranges. In other embodiments, the flow rate of the boron-and-halogen-containing precursor may be greater than the one or more halogen-containing precursors. For example, the flow rate ratio of the boron-and-halogen-containing precursor relative to the one or more halogen-containing precursors may be greater than or about 1:1, greater than or about 2:1, greater than or about 3:1, greater than or about 4:1, greater than or about 5:1, or more.

The plasma effluents formed from the precursors may be formed locally in the processing region or in a remote plasma system. For example, the plasma effluents may be generated by a remote plasma source (RPS), a capacitively coupled plasma (CCP), or an inductively coupled plasma (ICP) with or without one or more carrier gases such as Ar, He, diatomic nitrogen (N₂), H₂, or mixtures thereof. The plasma effluents may be a low-level plasma to limit the amount of bombardment and resultant sputtering, potential for clogging of the aperture 420, and/or bending/bowing of the feature 430. In embodiments the plasma power may be less than or about 5,000 W, and may be less than or about 4,500 W, less than or about 4,000 W, less than or about 3,500 W, less than or about 3,000 W, less than or about 2,500 W, less than or about 1,500 W, less than or about 1,000 W, less than or about 750 W, less than or about 500 W, or less, although the plasma power may also be included in ranges between any two of these stated numbers or within any smaller range encompassed by any of the stated ranges. By utilizing a low-level plasma power, the plasma effluents may be better controlled for delivery through the apertures 420 of the layer of silicon-containing material 415, while limiting sputtering of the layer of silicon-containing material 415 as well as other exposed surfaces.

As illustrated in FIG. 4C, the resultant feature 430 may extend through the layer of metal-containing hardmask material 410. While the aspect ratio and depth of the etched feature 430 may depend on the thicknesses of the layer of metal-containing hardmask material 410, the feature 430 may be characterized by an aspect ratio, or height to width measured from an upper surface of the substrate 405 to an upper surface of the layer of metal-containing hardmask material 410, of greater than or about 2:1. In embodiments, the feature 430 may be characterized by an aspect ratio of greater than or about 3:1, greater than or about 4:1, greater than or about 5:1, greater than or about 10:1, greater than or about 15:1, greater than or about 20:1, greater than or about 25:1, greater than or about 40:1, greater than or about 50:1, or more, although the aspect ratio may also be included in ranges between any two of these stated numbers or within any smaller range encompassed by any of the stated ranges. Additionally, a depth of the feature 430, measured from an upper surface of the substrate 405 to an upper surface of the layer of metal-containing hardmask material 410 may be greater than or about 20 nm, and may be greater than or about 30 nm, greater than or about 40 nm, greater than or about 50 nm, greater than or about 75 nm, greater than or about 100 nm, greater than or about 200 nm, greater than or about 300 nm, greater than or about 400 nm, greater than or about 500 nm, greater than or about 750 nm, greater than or about 1,000 nm, greater than or about 2,000 nm, greater than or about 3,000 nm, greater than or about 4,000 nm, greater than or about 5,000 nm, or more, although the depth may also be included in ranges between any two of these stated numbers or within any smaller range encompassed by any of the stated ranges. A critical dimension or width of the feature 430 may be less than or about 150 nm, and may be less than or about 125 nm, less than or about 100 nm, less than or about 75 nm, less than or about 50 nm, less than or about 45 nm, less than or about 40 nm, less than or about 35 nm, less than or about 30 nm, less than or about 28 nm, less than or about 26 nm, less than or about 24 nm, less than or about 22 nm, less than or about 20 nm, less than or about 19 nm, less than or about 18 nm, less than or about 17 nm, less than or about 16 nm, less than or about 15 nm, or less, although the critical dimension or width may also be included in ranges between any two of these stated numbers or within any smaller range encompassed by any of the stated ranges.

The increased etch rate of the layer of metal-containing hardmask material 410 may also result in an increased etch selectivity between the layer of metal-containing hardmask material 410 and the layer of silicon-containing material 415. In embodiments, the contacting may selectively etch the layer of metal-containing hardmask material 410 relative to the layer of silicon-containing material 415 at a selectivity of greater than or about 2:1, and may be greater than or about 3:1, greater than or about 4:1, greater than or about 5:1, greater than or about 6:1, greater than or about 7:1, greater than or about 8:1, greater than or about 9:1, greater than or about 10:1, greater than or about 15:1, greater than or about 20:1, greater than or about 25:1, greater than or about 30:1, or more, although the etch selectivity may also be included in ranges between any two of these stated numbers or within any smaller range encompassed by any of the stated ranges.

Process conditions may also impact the operations performed in method 300. Each of the operations of method 300 may be performed during a constant temperature in embodiments, while in some embodiments the temperature may be adjusted during different operations. For example, a semiconductor processing chamber operating temperature, which may include the substrate, pedestal, or chamber temperature, during the method 300 may be maintained at a temperature greater than or about 20° C., and in some embodiments the temperature may be maintained greater than or about 50° C., greater than or about 75° C., greater than or about 100° C., greater than or about 150° C., greater than or about 200° C., greater than or about 250° C., greater than or about 300° C., greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., or more, although the temperature may also be included in ranges between any two of these stated numbers or within any smaller range encompassed by any of the stated ranges. For example, the semiconductor processing chamber operating temperature may be between about 300° C. about 500° C., or between any other values previously stated.

The pressure within the processing chamber may be controlled during method 300. For example, while forming the plasma effluents and performing the etching operation, the semiconductor processing chamber operating pressure may be maintained below at less than or about 50 mTorr, and may be maintained at less than or about 45 mTorr, less than or about 40 mTorr, less than or about 35 mTorr, less than or about 30 mTorr, less than or about 25 mTorr, less than or about 20 mTorr, less than or about 15 mTorr, less than or about 10 mTorr, less than or about 5 mTorr, or less, although the pressure may also be included in ranges between any two of these stated numbers or within any smaller range encompassed by any of the stated ranges. The pressure within the processing chamber may affect the capabilities of flow into the aperture 420. For example, as pressure increases, plasma effluents may have increased difficulty in permeating the aperture 420 and reaching an etch front of the feature 430.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a boron-and-halogen-containing precursor and an oxygen-containing precursor to a processing region of a semiconductor processing chamber, wherein a substrate is housed in the processing region, wherein a layer of metal-containing hardmask material is disposed on the substrate, and wherein a layer of silicon-containing material is disposed on the layer of metal-containing hardmask material;
forming plasma effluents of the boron-and-halogen-containing precursor and the oxygen-containing precursor; and
contacting the substrate with the plasma effluents of the boron-and-halogen-containing precursor and the oxygen-containing precursor, wherein the contacting etches a feature in the layer of metal-containing hardmask material, and wherein the contacting forms a layer of passivation material on sidewalls of the feature in the layer of metal-containing hardmask material.

2. The semiconductor processing method of claim 1, wherein the boron-and-halogen-containing precursor comprises boron trichloride (BCl₃).

3. The semiconductor processing method of claim 1, wherein the oxygen-containing precursor comprises diatomic oxygen (O₂).

4. The semiconductor processing method of claim 1, wherein the layer of metal-containing hardmask material comprises tungsten.

5. The semiconductor processing method of claim 1, further comprising:
providing a halogen-containing precursor to the processing region with the boron-and-halogen-containing precursor.

6. The semiconductor processing method of claim 1, wherein the halogen-containing precursor comprises diatomic chlorine (Cl₂), hydrogen bromide (HBr), or both.

7. The semiconductor processing method of claim 1, wherein the layer of metal-containing hardmask material is characterized by a metal content of greater than or about 40 at. %.

8. The semiconductor processing method of claim 1, wherein the layer of silicon-containing material comprises silicon oxide.

9. The semiconductor processing method of claim 1, wherein the layer of passivation material comprises a boron-and-oxygen-containing material.

10. The semiconductor processing method of claim 1, wherein the feature in the layer of metal-containing hardmask material is characterized by a critical dimension of less than or about 20 nm.

11. The semiconductor processing method of claim 1, wherein the semiconductor processing chamber operating temperature is greater than or about 20° C.

12. The semiconductor processing method of claim 1, wherein the boron-and-halogen-containing precursor and the oxygen-containing precursor are silicon-free.

13. A semiconductor processing method comprising:
i) providing a boron-and-halogen-containing precursor to a processing region of a semiconductor processing chamber, wherein a substrate is housed in the processing region, wherein a layer of metal-containing hardmask material is disposed on the substrate, and wherein a layer of silicon-containing material is disposed on the layer of metal-containing hardmask material;
ii) forming plasma effluents of the boron-and-halogen-containing precursor;
iii) contacting the substrate with the plasma effluents of the boron-and-halogen-containing precursor, wherein the contacting etches a feature in the layer of metal-containing hardmask material;
iv) providing an oxygen-containing precursor to the processing region of the semiconductor processing chamber; and
v) contacting the substrate with the oxygen-containing precursor, wherein the contacting oxidizes a portion of sidewalls of the feature in the layer of metal-containing hardmask material.

14. The semiconductor processing method of claim 13, further comprising:
providing one or more halogen-containing precursors to the processing region of the semiconductor processing chamber with the boron-and-halogen-containing precursor.

15. The semiconductor processing method of claim 14, wherein a flow rate ratio of the one or more halogen-containing precursors relative to the boron-and-halogen-containing precursor is greater than or about 50:1.

16. The semiconductor processing method of claim 13, wherein operations i) through v) are repeated for a second cycle.

17. The semiconductor processing method of claim 16, wherein repeating operation iii) in the second cycle forms a layer of passivation material on the sidewalls of the feature in the layer of metal-containing hardmask material.

18. A semiconductor processing method comprising:
providing a boron-and-halogen-containing precursor to a processing region of a semiconductor processing chamber, wherein a substrate is housed in the processing region, wherein a layer of metal-containing hardmask material is disposed on the substrate, and wherein a patterned layer of silicon-containing material is disposed on the layer of metal-containing hardmask material;
forming plasma effluents of the boron-and-halogen-containing precursor;
contacting the substrate with the plasma effluents of the boron-and-halogen-containing precursor, wherein the contacting etches a first portion of a feature in the layer of metal-containing hardmask material, providing an oxygen-containing precursor to the processing region of the semiconductor processing chamber;
contacting the substrate with the oxygen-containing precursor, wherein the contacting oxidizes sidewalls of the feature in the layer of metal-containing hardmask material;
providing the boron-and-halogen-containing precursor to the processing region of the semiconductor processing chamber;
forming plasma effluents of the boron-and-halogen-containing precursor; and
contacting the substrate with the plasma effluents of the boron-and-halogen-containing precursor, wherein the contacting etches a second portion of the feature in the layer of metal-containing hardmask material, and wherein the contacting forms a layer of passivation material on sidewalls of the feature in the layer of metal-containing hardmask material.

19. The semiconductor processing method of claim 18, wherein the boron-and-halogen-containing precursor comprises boron trichloride (BCl₃).

20. The semiconductor processing method of claim 18, further comprising:
forming plasma effluents of the oxygen-containing precursor.
